(19) United States
(12) Patent Application Publication
(10) Pub. No.: US 2008/0082889 A1
(43) Pub. Date: Apr. 3, 2008

(54) SEMICONDUCTOR TEST SYSTEM

(75) Inventor: Tatsuyuki Agata, Tokyo (JP)

Correspondence Address: SUGHRUE-265550, 2100 PENNSYLVANIA AVE. NW, WASHINGTON, DC, 20037-3213, US

(73) Assignee: YOKOGAWA ELECTRIC CORPORATION, Musashino-shi (JP)

(21) Appl. No.: 11/862,237

(22) Filed: Sep. 27, 2007

(30) Foreign Application Priority Data
Sep. 28, 2006 (JP) 2006-264758

(51) Int. Cl. G01R 31/3177

(52) U.S. Cl. 714/744; 714/E11.144

(57) ABSTRACT

This invention provides a semiconductor test system including a test pattern generating portion for generating a test pattern data including a test signal for testing a device under test, at a predetermined timing, a driver for inputting the test pattern data generated by the test pattern generating portion into the device under test by way of a transmission line, and an adjustment DA converter for setting a voltage value of a high level or a low level signal inputted by the driver, to a voltage value of an adjustment high level or an adjustment low level adjusted in accordance with a characteristic of the transmission line.

This application is based on and claims priority from Japanese Patent Application No. 2006-264758, filed on Sep. 28, 2006, the entire contents of which are hereby incorporated by reference.

### BACKGROUND OF THE INVENTION

1. Technical Field

The present invention relates to a semiconductor test system for testing a device under test such as a memory device and an IC device, particularly relates to a circuit configuration for inputting a test signal to a device under test in accordance with a characteristic of a transmission line.

2. Background Art

In a background art, there is a semiconductor test system for inputting a test signal to a device under test (hereinafter, referred to as DUT) such as a memory device and an Integrated Circuit (IC) device and testing whether DUT is operated normally based on a signal outputted in accordance with the test signal. According to a semiconductor test system of this kind, based on a pattern address generated by a timing generator (TG), a tester controller (TSC) outputs a pattern data that is read from a hard disk (HDD), from a pattern generator (PG). Further, a driver (DRV) transmits a test signal that is obtained from the pattern data to DUT, and a comparator (CMP) compares a signal from DUT with a desired level in order to carry out the test.(See, e.g., Patent Document: JP-A-2000-292500 (FIG. 1))

Meanwhile, in recent times, a semiconductor test system tends to be brought into multipins formation by more and more increasing a number of pieces of pin electronics at inside of a main body thereof Therefore, a number of pieces of cables of a transmission line connecting the main body of the semiconductor test system and DUT are increased and the cables are prolonged, and a distance between a driver or a comparator at inside of the main body and DUT is more and more tends to be remote from each other.

According to the semiconductor test system of this kind, in order to correctly test DUT transmitting the signal at high speed, it is strongly requested that a timing of a test signal of an input waveform or the like is always accurate. However, when the transmission line is increased or prolonged as described above, thereby, an influence is effected on a transmission speed of the signal. For example, although a coaxial cable or the like is used for the transmission line, the more increased the distance between the pin electronics circuit and DUT, the more prolonged the total length and the more increased the number of pins; the slenderer the transmission line. The characteristic of the transmission line is deteriorated by prolonging or slenderizing the transmission line and an adjustment for inputting the test signal at an accurate timing for testing DUT becomes extremely difficult.

Further specifically, when a certain waveform of a test signal is inputted from a driver to DUT, even when an ideal waveform is inputted, depending on a frequency characteristic of the transmission line, rise time or fall time of the waveform is changed. When the waveform reaches DUT, the waveform becomes dull in comparison with that at a time point before passing the transmission line. Therefore, for example, when a time period required for rise and fall (so-called turn on/turn off time period) becomes longer than a pulse width, since actual rise or fall is delayed, a prescribed high level or low level cannot be reached within the pulse width. Then, with regard to a waveform accompanied by a change from the high level to the low level or from the low level to the high level by a minimum pulse width, before the actual waveform reaches the high level or the low level completely, successive fall or rise is started. Therefore, in this case, the threshold level is reached at an early timing. Thus, there are problems that a shift in timing for inputting a signal to DUT arises.

In this way, when DUT of a high speed device is tested, a degree of change in an input signal to DUT becomes dull depending on the characteristic of the transmission line. Thus, in a high speed transmission, a waveform of the signal cannot reach a prescribed high level or low level, or a timing error arises.

### SUMMARY OF THE INVENTION

The present invention provides a semiconductor test system capable of preventing a timing error by a characteristic of a transmission line to DUT.

In order to resolve the above-described problem, a semiconductor test system according to the present invention comprises:

a test pattern generating portion for generating a test pattern data including a test signal for testing a device under test, at a predetermined timing;

a driver for inputting the test pattern data generated by the test pattern generating portion into the device under test by way of a transmission line; and

an adjustment DA converter for setting a voltage value of a high level or a low level signal inputted by the driver, to a voltage value of an adjustment high level or an adjustment low level adjusted in accordance with a characteristic of the transmission line.

According to the configuration, the adjustment DA converter can set the voltage value of the signal of the high level or the low level inputted by the driver, to the voltage value of the adjustment high level or the adjustment low level adjusted in accordance with the characteristic of the transmission line. Therefore, the waveform in accordance with the adjustment high level or the adjustment low level is obtained, and when a time period of a minimum pulse width has elapsed, the waveform of the signal is adjusted to reach the prescribed high level or low level, and the above-described timing error can be prevented from arising.

Further, another semiconductor test system according to the present invention comprises:

a test pattern generating portion for generating a test pattern data including a test signal for testing a device under test, at a predetermined timing;

a driver for inputting the test pattern data generated by the test pattern generating portion into the device under test by way of a transmission line;

a first DA converter for setting a voltage value of a signal of a high level inputted by the driver;

a second DA converter for setting a voltage value of a signal of a low level inputted by the driver;

a first adjustment DA converter for setting the voltage value of the signal of the high level inputted by the driver, to a voltage value of an adjustment high level adjusted in accordance with a characteristic of the transmission line in rising from the low level to the high level; and

a second adjustment DA converter for setting the voltage value of the signal of the low level inputted by the driver, to a voltage value of an adjustment low level adjusted in accordance with the characteristic of the transmission line in falling from the high level to the low level.

According to the configuration, the first and the second adjustment DA converters can set the voltage value of the signal of the high level or the low level inputted by the driver, to the voltage value of the adjustment high level or the adjustment low level adjusted in accordance with the characteristic of the transmission line in rising or falling thereof Therefore, a waveform actually transmitted in rising or falling of an output waveform corresponds to the adjustment high level or the adjustment low level. When the time period of the minimum pulse width has elapsed, the waveform of the signal is adjusted to reach the prescribed high level or low level. Therefore, the timing error can be prevented from arising.

Another semiconductor test system according to the invention comprises a test pattern generating portion for generating a test pattern data including a test signal for testing a device under test, at a predetermined timing;

a driver for inputting the test pattern data generated by the test pattern generating portion into the device under test by way of a transmission line;

a first DA converter for setting a voltage value of a signal of a high level inputted by the driver;

a second DA converter for setting a voltage value of a signal of a low level inputted by the driver;

a first adjustment DA converter for setting the voltage value of the signal of the high level inputted by the driver, to a voltage value of an adjustment high level higher than the high level set by the first DA converter in rising from the low level to the high level; and

a second adjustment DA converter for setting the voltage value of the signal of the low level inputted by the driver, to a voltage value of an adjustment low level lower than the low level set by the second DA converter in falling from the high level to the low level.

According to the configuration, the first and the second adjustment DA converters can set the voltage value of the signal of the high level or the low level inputted by the driver, to the voltage value of the adjustment high level higher than the high level set by the first, the second DA converters, or the voltage value of the adjustment low level lower than the low level set thereby in rising or falling thereof. Therefore, the actually transmitted waveform corresponds to the adjustment high level or the adjustment low level in rising or falling of the output waveform. In this case, even when an actual time period of rising or falling becomes longer than the minimum pulse width, the waveform of the signal is adjusted to reach the prescribed high level or low level when the time period of the minimum pulse width has elapsed. Therefore, the timing error can effectively be prevented from arising.

Further, according to the above-described semiconductor test system, the first and the second adjustment DA converters may set the voltage value of the signal of the high level or the low level, which is inputted by the driver, to the voltage value of the adjustment high level or the voltage value of the adjustment low level only during a time interval of a minimum pulse width in rising or falling thereof.

In this case, waveform of the signal is adjusted during the time period of the minimum pulse width so that the timing error is prevented, and then the test signal of the waveform is inputted with the level of which is recovered to the prescribed level.

Further, according to the above-described semiconductor test system, the semiconductor test system may further comprise:

a first adjustment control portion for variably controlling the voltage value of the adjustment high level set by the first adjustment DA converter; and

a second adjustment control portion for variably controlling the voltage value of the adjustment low level set by the second adjustment DA converter.

According to the configuration, the adjustment control portion variably controls the voltage values of the adjustment high level and the adjustment low level set by the first and the second adjustment DA converters in accordance with various characteristics of the transmission line, so that the timing error can be prevented.

Further, according to the above-described semiconductor test system, the first adjustment DA converter may comprise:

high level storing means for storing a plurality of kinds of the voltage values of the adjustment high level; and

high level selecting means for selecting any of the voltage values stored in the high level storing means to set to the voltage value of the signal of the high level inputted by the driver, and the second adjustment DA converter may comprise:

low level storing means for storing a plurality of kinds of the voltage values of the adjustment low level; and

low level selecting means for selecting any of the voltage values stored in the low level storing means to set to the voltage value of the signal of the low level inputted by the driver.

According to the configuration, in accordance with the characteristic of the transmission line, the high level selecting means and the low level selecting means change the voltage values of the adjustment high level and the adjustment low level to set to any thereof, so that the error timing can be effectively prevented.

According to the semiconductor test system according to the present invention, the timing error arising from the characteristic of the transmission line to DUT can be prevented.

### BRIEF DESCRIPTION OF THE DRAWINGS

FIG. 1 is an explanatory diagram showing a configuration of a semiconductor test system according to an embodiment of the present invention;

FIG. 2 is an explanatory view showing a configuration of a semiconductor test system according to a comparative example of the present invention;

FIGS. 3A and 3B illustrate explanatory diagrams showing waveforms of test signals of the semiconductor test system according to the embodiment of the present invention;

FIGS. 4A and 4B illustrate explanatory diagrams showing waveforms of the test signals reaching DUT through a transmission line of the semiconductor test system according to the embodiment of the present invention;

FIG. 5 is an explanatory diagram showing the waveform of the test signal of the semiconductor test system according to the embodiment of the present invention;

FIGS. 6A and 6B illustrate explanatory diagrams showing waveforms of test signals of the semiconductor test system according to the comparative example of the present invention;

FIGS. 7A and 7B illustrate explanatory diagrams showing the waveform of the test signal of the semiconductor test system according to the comparative example of the present invention; and

FIGS. 8A and 8B illustrate explanatory diagrams showing waveforms of test signals reaching DUT through a transmission line of the semiconductor test system according to the comparative example of the present invention.

### DESCRIPTION OF EXEMPLARY EMBODIMENTS

The best mode for carrying out the invention will be explained in details in reference to the drawings as follows.

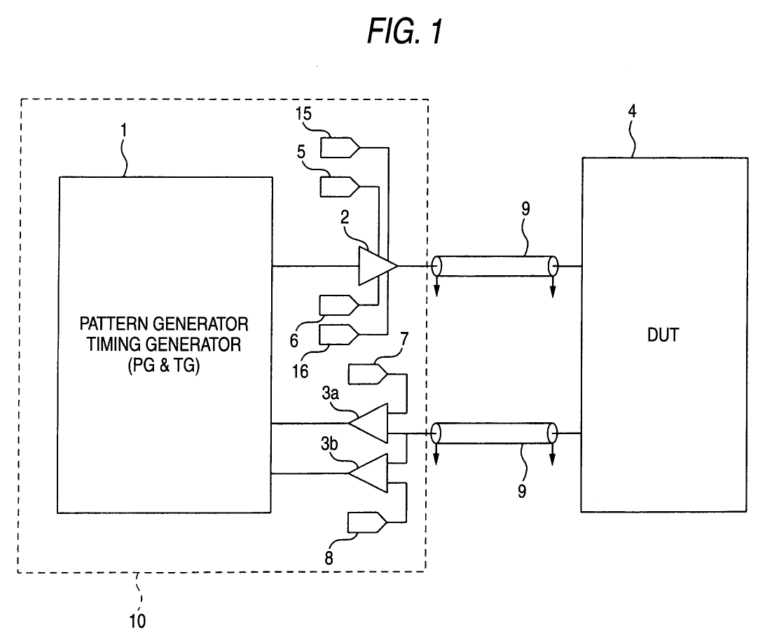

FIG. 1 is an explanatory view showing a configuration of a semiconductor test system 10 according to the embodiment of the present invention. The semiconductor test system 10 includes a pattern generator (PG) and a timing generator (TG). In the following, the pattern generator and the timing generator are designated by notation PG&TG1 for simplification. A driver 2 is connected to PG&TG1 and similarly, comparators 3a, 3b are connected to PG&TG1.

Further, the semiconductor test system 10 includes DA converters 5, 6. The DA converter 5 on one side sets a voltage value of a signal at a high level inputted to DUT 4 by the driver 2. The DA converter 6 on the other side sets a voltage value of a signal at a low level inputted to DUT 4 by the driver 2. Further, DUT 4 is a semiconductor device constituting an object of test, such as a memory device and an IC device.

Further, the semiconductor test system 10 includes a DA converter 7, a DA converter 8, an adjustment DA converter 15 and an adjustment DA converter 16. The DA converter 7 sets a threshold value on a high level side for determining a signal outputted from DUT by the comparator 3a. The DA converter 8 sets a threshold value on a low level side for determining a signal outputted from DUT 4 by the comparator 3a. The adjustment DA converter 15 sets a voltage value of a signal at a high level, which is inputted to DUT 4 by the driver 2, to a voltage value at an adjustment high level adjusted in accordance with a characteristic of a transmission line 9 mentioned later. The adjustment DA converter 16 sets a voltage value of a signal at a low level, which is inputted to DUT 4 by the driver 2, to a voltage value at an adjustment low level adjusted in accordance with the characteristic of the transmission line 9 mentioned later. The driver 2 and the comparators 3a, 3b are connected to DUT 4 respectively through the transmission lines 9.

The PG&TG1 generates a test pattern data stored in a memory or the like (not illustrated) by a predetermined timing to output to the driver 2. Further, a memory or the like (not illustrated) stores data of an expected value and a comparison timing for comparing a signal outputted from DUT 4. The PG&TG1 compares signals outputted from the comparators 3a, 3b with the expected value.

Further, the PG&TG1 analyzes a test pattern data and transmits an instruction code for setting a target value thereof to a voltage value at an adjustment high level, to the adjustment DA converter 15 at a rise timing of a waveform of a test signal from a low level to a high level. Further, the PG&TG1 transmits an instruction code for setting the target value to a voltage value at an adjustment low level, to the adjustment DA converter 16 at a fall timing of the waveform of the test signal from the high level to the low level. Further, a further description will be given with regard to setting the voltage values at an adjustment high level and at an adjustment low level.

The driver 2 inputs the test signal of the waveform based on the test pattern data outputted from PG&TG1 to DUT 4 by way of the transmission line 9. Thereby, the signals at the high level, at the low level, at the adjustment high level and at the adjustment low level are outputted by the voltage values in accordance with respective settings of the DA converters 5, 6 and the adjustment DA converters 15, 16.

The comparator 3a is provided with a function of comparing the signal outputted from DUT 4 by way of the transmission line 9 with a threshold of a side of a high level set by the DA converter 7 and converting the signal into a logic signal at a high level based on a result of comparison to output to PG&TG1.

The comparator 3b compares the signal that is outputted from DUT 4 through the transmission line 9, with a threshold value on a low level side set by the DA converter 8, and converts the signal into a logic signal at a low level based on a comparison result to output to PG&TG1.

The DA converter 5 sets a voltage value of a signal of a high level when the driver 2 inputs the signal at the high level to DUT 4. The DA converter 6 sets a voltage value of a signal at a low level when the driver 2 inputs the signal at the low level to DUT 4. Further, the transmission line 9 is a cable for transmitting a signal of a coaxial cable, for example.

The adjustment DA converter 15 sets the voltage value of the signal at the high level, which is inputted by the driver 2 to DUT 4, to a voltage value at an adjustment high level only during a time interval of a minimum pulse width in rising of the waveform of the test signal from low level to high level.

Here, the voltage value at the adjustment high level becomes higher than a voltage value set by the DA converter 5, and becomes a virtual target value when a rising time period is prolonged by a characteristic of the transmission line 9. Further, in actual rising, the voltage value is adjusted to pass through a voltage value similar to that set by the DA converter 5 when a time period of a minimum pulse width has elapsed. The voltage value is previously calculated and set based on the characteristic of the transmission line 9 or a characteristic of the driver 2 or the like.

The adjustment DA converter 16 sets a voltage value of a signal at a low level, which is inputted to DUT 4 by the driver 2, to a voltage value at an adjustment low level only during a time interval of a minimum pulse width in falling of the waveform of the test signal from a high level to a low level.

The voltage value at the adjustment low level becomes lower than a voltage value set by the DA converter 6 conversely to the adjustment high level and becomes a virtual target value when a falling time period is prolonged by the characteristic of the transmission line 9. Further, in actual falling, the voltage value is adjusted to pass through a voltage value similar to that set by the DA converter 6 when a time period of the minimum pulse width has elapsed and is previously calculated and set based on the characteristic of the transmission line 9 or the characteristic of the driver 2 or the like.

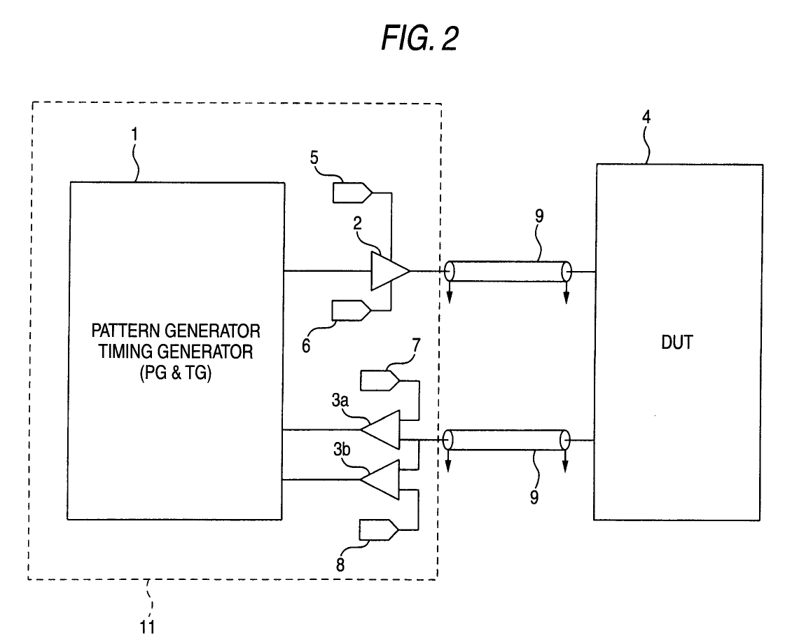

FIG. 2 is an explanatory view showing a configuration of a semiconductor test system 11 as a comparative example compared with the semiconductor test system 10 of the embodiment. The semiconductor test system 11 of the comparative example includes PG&TG1, the driver 2, the comparators 3a, 3b, the DA converter 5, the DA converter 6, the DA converter 7, and the DA converter 8. Further, according to the semiconductor test system 11, the driver 2 and the comparators 3a, 3b are connected to DUT 4 as an object of carrying out a test by the semiconductor test system 11 through the transmission line 9.

As is apparent from comparison between the semiconductor test system 10 of the present embodiment and the semiconductor test system 11 of the comparative example, the semiconductor test system 10 of the present embodiment differs from the semiconductor test system 11 of the comparative example with respect to configurations that the adjustment DA converters 15, 16 are provided other than the DA converters 5, 6.

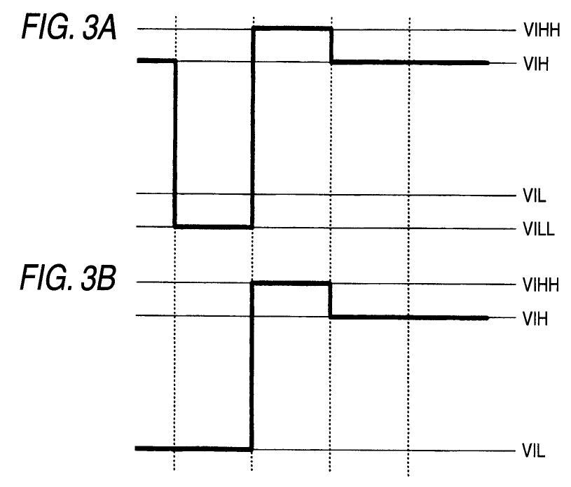

Next, a detailed explanation will be given of operation of the semiconductor test system 10 according to the present embodiment with reference to FIGS. 3 to 5.

### FIRST EXAMPLE

FIGS. 3A and 3B illustrate diagrams showing waveforms of test pattern data generated by the PG&TG1 in the semiconductor test system 10 of the present embodiment. The waveforms respectively show logical values having a high level of “1” and a low level of “0”. Assume a case in which the PG&TG1 generate test pattern data by the waveforms to output to the driver 2 at predetermined timings.

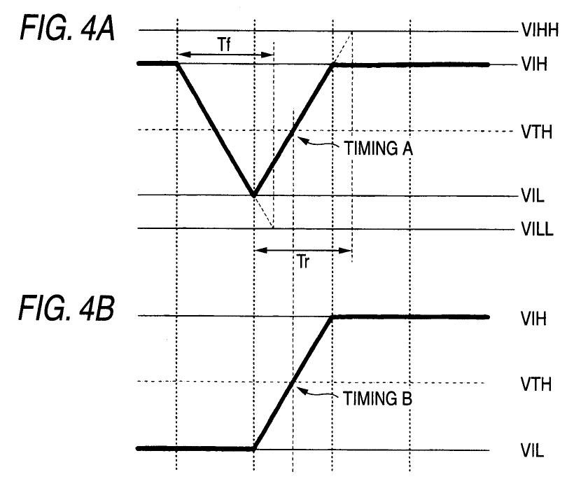

In this case, as shown in FIGS. 4A and 4B, the driver 2 outputs test signals of the waveforms based on the test pattern data, which is ideal waveforms, to DUT 4 through the transmission line 9 respectively. At this occasion, during a time period of a minimum pulse width in rising from the low level to the high level, or in falling from the high level to the low level, voltage values of the signals of the high level VIH and the low level VIL are respectively set to voltage values of an adjustment high level VIHH and an adjustment low level VILL by the adjustment DA converters 15 and 16. Thus, the driver 2 outputs the signals of the voltage values after setting the voltage values as so-called target values.

Then, as shown in FIG. 4A, in the case of fall, a slope of the waveform of the test signal that reaches DUT 4 through the transmission line 9 falls down to the voltage value of the adjustment low level VILL at a time width of a time period Tf depending on the characteristic of the transmission line 9. Thereby, when a time period of an inherent minimum pulse width of the waveform of the test signal has elapsed, a voltage value of the low level VIL inherently set by the DA converter 6 is reached. At the time point, the waveform of the test signal is folded back without reaching the adjustment low level VILL and rises towards the adjustment high level HILL at this time.

Further, in the case of rise, as shown in FIGS. 4A and 4B, a slope of the waveform of the test signal rises to the voltage value of the adjustment high level VIHH at a time width of a time period Tr depending on the characteristic of the transmission line 9. Further, when the time period of the inherent minimum pulse width of the waveform of the test signal has elapsed, a voltage value of the high level VIH set by the DA converter 5 is reached. At this moment, the voltage value of the signal of the driver 2 becomes the high level VIH. Therefore, the voltage value is held without reaching the adjustment high level VIHH.

In this way, according to the embodiment, even when time periods of rise and fall are prolonged by the characteristic of the transmission line 9, the target voltage values at time of changes are set to the adjustment high level VIHH and the adjustment low level VILL. Therefore, the slopes of rise and fall of actual waveforms become larger than inherent slopes. However, the waveforms of the actual test signals do not reach the adjustment high level VIHH and the adjustment low level VILL respectively within the time periods Tf and Tr but reach substantially the high level VIH and the low level VIL after elapse of the time periods of the minimum pulse width. Therefore, there are provided waveforms substantially the same as those when the waveforms are not influenced by timings by the characteristic of the transmission line 9. Therefore, in timings of reaching the threshold level VTH, Timing A in FIG. 4A and Timing B in FIG. 4B coincide with each other and a timing error therebetween does not arise.

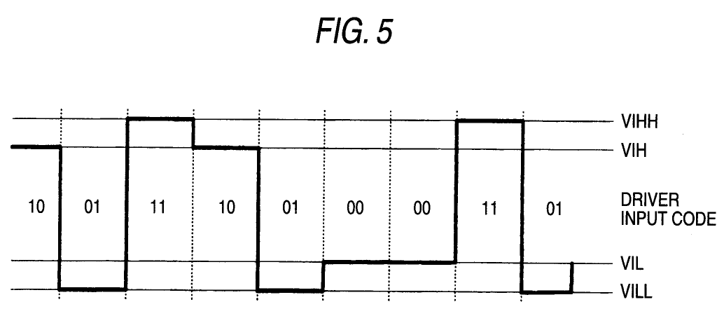

As a result, as shown in FIG. 5, in respective pulse width time periods, logical values “00”, “01”, “10”, “11” are accurately reproduced, and therefore, a failure is not brought about in a signal applied to DUT 4.

### COMPARATIVE EMAMPLE

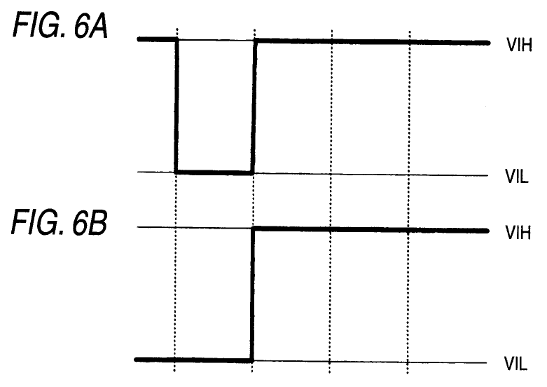

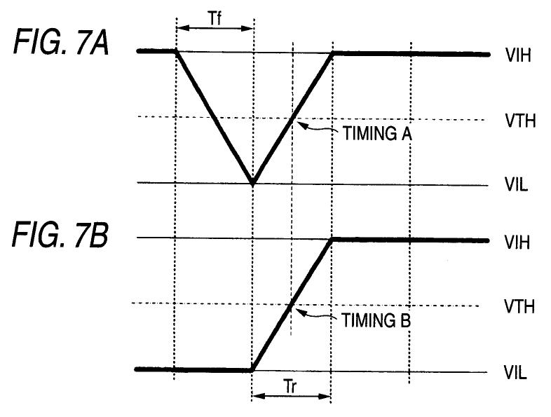

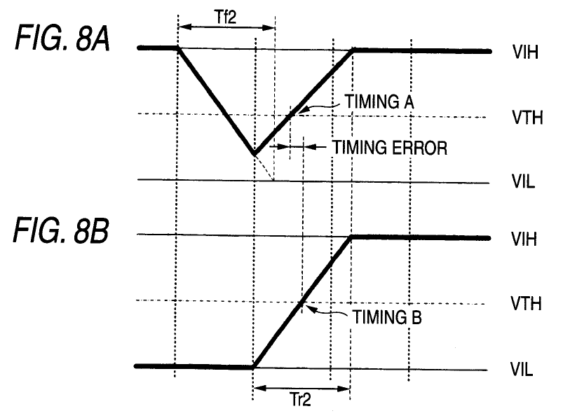

FIGS. 6A and 6B illustrate diagrams showing waveforms of a test pattern generated by PG&TG1 in the semiconductor test system 11 of a comparative example. In the semiconductor test system 11 of the comparative example, as shown in FIGS. 7A to 8B, the driver 2 outputs signals of voltage values set by the DA converters 5 and 6 in rising and in falling. In the diagrams, FIGS. 7A and 7B show examples expecting completion of changes from the high level to the low level and from the low level to the high level within time periods Tf and Tr. In contrast thereto, FIGS. 8A and 8B show examples in which a time period Tf2 and a time period Tr2 are required for actual changes by influence of the characteristic of the transmission line 9.

In this way, when the time periods of rise and fall are prolonged by the characteristic of the transmission line 9, the waveforms of the test signals that reaches DUT 4 through the transmission line 9 become slopes (more gradual than expected slopes) of completing fall and rise by time period width of time periods Tf2 and Tr2 longer than expected time periods different from the slopes of the expected waveforms shown in FIGS. 7A and 7B. Therefore, when time periods of the minimum pulse width inherent to the waveforms of the test signal has elapsed, the voltage values of the high level VIH and the low level VIL are not reached. Therefore, actually, as shown in FIG. 8A, folding back arises before reaching the voltage value of the low level VIL. As a result, in the timing of reaching the threshold value VTH, Timing A of FIG. 8A and Timing B of FIG. 8B do not coincide with each other and it is known that a timing error arises from the shift therebetween.

In this respect, in the semiconductor test system 10 according to the present embodiment, during the time periods of the minimum pulse width when the waveform of the test signal arises from the low level to the high level and when the waveform of the test signal falls from the high level to the low level, the driver 2 outputs the signals of the voltage values of the adjustment high level VIHH and the adjustment low level VILL set by the adjustment DA converters 15 and 16. Therefore, even when the time period of fall is prolonged by the characteristic of the transmission line 9, there are provided expected waveforms substantially the same as those when the slopes of rise and fall of the waveforms are not influenced by the characteristic of the transmission line 9. Therefore, a failure of the signal applied to DUT 4 by the timing error does not arise.

### SECOND EXAMPLE

In the above-described embodiment, there may be provided an adjustment control portion for variably controlling the voltage values of the adjustment high level VIHH and the adjustment low level VILL set by the adjustment DA converters 15 and 16. By such a configuration, even when the characteristic is changed by changing the transmission line 9 or the like, the voltage values of the adjustment high level VIHH and the adjustment low level VILL can be pertinently changed in accordance therewith.

Further, in one embodiment of the present invention, there may be provided a high level storing portion for storing a plurality of kinds of voltage values of the adjustment high level by the adjustment DA converter 15. In this case, there may be provided a high level selecting portion for selecting the voltage value stored in the storing portion and setting the voltage value to the voltage value of the signal of the high level inputted by the driver 2. Similarly, in one embodiment of the present invention, there may be provided a low level storing portion for storing a plurality of kinds of the voltage values of the adjustment low level by the adjustment DA converter 16. In this case, there may be provided a low level selecting portion for selecting any of the voltage values stored in the low level storing portion and setting the voltage value to the voltage value of the signal of the low level inputted by the driver 2. Also by such a constitution, the voltage value of the adjustment high level VIHH and the voltage value of the adjustment low level VILL can be changed in accordance with the change in the transmission line 9 or the like.

In one embodiment of the present invention, the voltage values of the adjustment high level and the adjustment low level respectively set by the adjustment DA converters 15 and 16 may be set in accordance with not only the characteristic of the transmission line 9 but also a characteristic such as a relay and a connector, which is interposed on a line from the driver 2 to DUT 4 and can influence on the waveform of the test signal.

Although in one embodiment of the present invention, the test signal is generated by PG&TG1 and is inputted to DUT 4 by way of the driver 2, the embodiment is not limited thereto but the configuration of the present embodiment can be used even in other signal or waveform so far as when some signal is inputted to an external circuit from the driver 2 by way of the transmission line 9.

Although in one embodiment of the present invention, the adjustment DA converters 15 and 16 set the waveform of the test signal to the voltage values of the adjustment high level and the adjustment low level respectively only during the time periods of the minimum pulse width in rising and in falling, the embodiment is not limited to the time width but may set the voltages by a plurality of pulse widths.

While there has been described in connection with the exemplary embodiments of the present invention, it will be obvious to those skilled in the art that various changes and modification may be made therein without departing from the present invention. It is aimed, therefore, to cover in the appended claim all such changes and modifications as fall within the true spirit and scope of the present invention.

What is claimed is:

1. A semiconductor test system comprising:
a test pattern generating portion for generating a test pattern data including a test signal for testing a device under test, at a predetermined timing;
a driver for inputting the test pattern data generated by the test pattern generating portion into the device under test by way of a transmission line; and
an adjustment DA converter for setting a voltage value of a high level or a low level signal inputted by the driver, to a voltage value of an adjustment high level or an adjustment low level adjusted in accordance with a characteristic of the transmission line.

2. A semiconductor test system comprising:
a test pattern generating portion for generating a test pattern data including a test signal for testing a device under test, at a predetermined timing;
a driver for inputting the test pattern data generated by the test pattern generating portion into the device under test by way of a transmission line;
a first DA converter for setting a voltage value of a signal of a high level inputted by the driver;
a second DA converter for setting a voltage value of a signal of a low level inputted by the driver;
a first adjustment DA converter for setting the voltage value of the signal of the high level inputted by the driver, to a voltage value of an adjustment high level adjusted in accordance with a characteristic of the transmission line in rising from the low level to the high level; and
a second adjustment DA converter for setting the voltage value of the signal of the low level inputted by the driver, to a voltage value of an adjustment low level adjusted in accordance with the characteristic of the transmission line in falling from the high level to the low level.

3. A semiconductor test system comprising:
a test pattern generating portion for generating a test pattern data including a test signal for testing a device under test, at a predetermined timing;
a driver for inputting the test pattern data generated by the test pattern generating portion into the device under test by way of a transmission line;
a first DA converter for setting a voltage value of a signal of a high level inputted by the driver;
a second DA converter for setting a voltage value of a signal of a low level inputted by the driver;
a first adjustment DA converter for setting the voltage value of the signal of the high level inputted by the driver, to a voltage value of an adjustment high level higher than the high level set by the first DA converter in rising from the low level to the high level; and
a second adjustment DA converter for setting the voltage value of the signal of the low level inputted by the driver, to a voltage value of an adjustment low level lower than the low level set by the second DA converter in falling from the high level to the low level.

4. The semiconductor test system according to claim 2, wherein
the first and the second adjustment DA converters set the voltage value of the signal of the high level or the low level, which is inputted by the driver, to the voltage value of the adjustment high level or the voltage value of the adjustment low level only during a time interval of a minimum pulse width in rising or falling thereof.

5. The semiconductor test system according to claim 3, wherein
the first and the second adjustment DA converters set the voltage value of the signal of the high level or the low level, which is inputted by the driver, to the voltage value of the adjustment high level or the voltage value of the adjustment low level only during a time interval of a minimum pulse width in rising or falling thereof.

6. The semiconductor test system according to claim 2, further comprising:
a first adjustment control portion for variably controlling the voltage value of the adjustment high level set by the first adjustment DA converter; and
a second adjustment control portion for variably controlling the voltage value of the adjustment low level set by the second adjustment DA converter.

7. The semiconductor test system according to claim 3, further comprising:
a first adjustment control portion for variably controlling the voltage value of the adjustment high level set by the first adjustment DA converter; and
a second adjustment control portion for variably controlling the voltage value of the adjustment low level set by the second adjustment DA converter.

8. The semiconductor test system according to claim 4, further comprising:
a first adjustment control portion for variably controlling the voltage value of the adjustment high level set by the first adjustment DA converter; and
a second adjustment control portion for variably controlling the voltage value of the adjustment low level set by the second adjustment DA converter.

9. The semiconductor test system according to claim 5, further comprising:
a first adjustment control portion for variably controlling the voltage value of the adjustment high level set by the first adjustment DA converter; and
a second adjustment control portion for variably controlling the voltage value of the adjustment low level set by the second adjustment DA converter.

10. The semiconductor test system according to claim 2, wherein the first adjustment DA converter comprises:
high level storing means for storing a plurality of kinds of the voltage values of the adjustment high level; and
high level selecting means for selecting any of the voltage values stored in the high level storing means to set to the voltage value of the signal of the high level inputted by the driver, and
the second adjustment DA converter comprises:
low level storing means for storing a plurality of kinds of the voltage values of the adjustment low level; and
low level selecting means for selecting any of the voltage values stored in the low level storing means to set to the voltage value of the signal of the low level inputted by the driver.
